(19) United States
(12) Patent Application Publication
(10) Pub. No.: US 2013/0258610 A1
(43) Pub. Date: Oct. 3, 2013

(54) SEMICONDUCTOR CHIP DEVICE WITH VENTED LID

(71) Applicants: Jianguo Li, Scarborough (CA); Neil McLellan, Austin, TX (US); Yip Seng Low, Thornhill (CA)

(72) Inventors: Jianguo Li, Scarborough (CA); Neil McLellan, Austin, TX (US); Yip Seng Low, Thornhill (CA)

(21) Appl. No.: 13/434,219

(22) Filed: Mar. 29, 2012

(51) Int. Cl. H05K 7/00; F28D 15/00; H05K 3/00

(52) U.S. Cl. 361/748; 29/829; 165/104.19; 361/820

(57) ABSTRACT

Various circuit board lids and methods and using the same are disclosed. In one aspect, an apparatus is provided that includes a lid adapted to cover a semiconductor chip mounted on a circuit board. The lid has a top plate, a first support leg and a second support leg opposite the first support leg adapted to support the lid. The first and second support legs and the top plate define a recess to accommodate the semiconductor chip. The recess has a first opening and a second opening. At least one of the first and second openings extends from the first support leg to the second support leg.

### BACKGROUND OF THE INVENTION

1. Field of the Invention

This invention relates generally to semiconductor processing, and more particularly to circuit board lids and to methods of making and using the same.

2. Description of the Related Art

Many current integrated circuits are formed as multiple dice on a common silicon wafer. After the basic process steps to form the circuits on the dice are complete, the individual dice are cut or singulated from the wafer. The singulated dice are then usually mounted to structures, such as circuit boards, or packaged in some form of enclosure.

One frequently-used package consists of a substrate on which a die is mounted. After the die is mounted to the substrate, a lid is attached to the substrate to cover the die. Some conventional integrated circuits, such as microprocessors and graphics processors, generate sizeable quantities of heat that must be ferried away to avoid device shutdown or damage. For these devices, the lid serves as both a protective cover and a heat transfer pathway. A thermal interface material is disposed on the die to provide a thermal pathway to the lid.

Two types of conventional lids include bathtub and top hat configurations. Each of these designs incorporates four orthogonal walls that project downwardly from a top plate to define an internal recess. In many conventional designs, the walls are continuous, and in conjunction with an adhesive bead on the substrate, hermetically seal the die. Such designs do not permit ambient gases, such as air, to flow through the recess and provide cooling to the die. In a few other conventional lid designs, the walls are not continuous. Instead, the lid walls include small vents that lead to the internal recess.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes fabricating a lid that is adapted to cover a semiconductor chip mounted on a circuit board. The lid has a top plate, a first support leg and a second support leg opposite the first support leg that are adapted to support the lid on the circuit board. The first and second support legs and the top plate define a recess to accommodate the semiconductor chip. The recess has a first opening and a second opening. At least one of the first and second openings extends from the first support leg to the second support leg.

In accordance with another aspect of an embodiment of the present invention, a method of conveying heat from a semiconductor chip mounted on a circuit board is provided that includes coupling a lid to the circuit board and in thermal contact with the semiconductor chip. The lid has a top plate, a first support leg and a second support leg opposite the first support leg that support the lid. The first and second support legs and the top plate define a recess to accommodate the semiconductor chip. The recess has a first opening and a second opening. At least one of the first and second openings extends from the first support leg to the second support leg to enable a gas to flow between the first and second openings to cool the semiconductor chip.

In accordance with another aspect of an embodiment of the present invention, an apparatus is provided that includes a lid adapted to cover a semiconductor chip mounted on a circuit board. The lid has a top plate, a first support leg and a second support leg opposite the first support leg adapted to support the lid. The first and second support legs and the top plate define a recess to accommodate the semiconductor chip. The recess has a first opening and a second opening. At least one of the first and second openings extends from the first support leg to the second support leg.

In accordance with another aspect of an embodiment of the present invention, an apparatus is provided that includes a circuit board, a semiconductor chip mounted on the circuit board, and a lid mounted on the circuit board. The lid has a top plate, a first support leg and a second support leg opposite the first support leg to support the lid. The first and second support legs and the top plate define a recess to accommodate the semiconductor chip. The recess has a first opening and a second opening. At least one of the first and second openings extends from the first support leg to the second support leg.

In accordance with another aspect of an embodiment of the present invention, a method of manufacturing is provided that includes fabricating a lid adapted to cover a semiconductor chip mounted on a circuit board. The lid has a top plate, a first support leg and a second support leg opposite the first support leg adapted to support the lid on the circuit board. The first and second support legs and the top plate define a recess to accommodate the semiconductor chip. The recess has a first opening and a second opening. At least one of the first and second openings extends between first support leg and the second support leg. At least one of the first and second openings is substantially at least as large as the recess.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that may include a lid or heat spreader mounted on a circuit board;

FIG. 2 is a partially exploded pictorial view of the exemplary embodiment of the semiconductor chip device of FIG. 1;

FIG. 3 is a sectional view of FIG. 1 taken at section 3-3;

FIG. 4 is a front view of a portion of the exemplary semiconductor chip device of FIG. 1;

FIG. 5 is a front view like FIG. 4, but of an alternate exemplary semiconductor chip device;

FIG. 6 is a pictorial view of an alternate exemplary embodiment of a semiconductor chip device that may include a lid or heat spreader mounted on a circuit board;

FIG. 7 is a front view of a portion of the exemplary semiconductor chip device of FIG. 6;

FIG. 8 is a front view like FIG. 7, but of an alternate exemplary semiconductor chip device;

FIG. 9 is a pictorial view of an alternate exemplary embodiment of a semiconductor chip device that may include a lid or heat spreader mounted on a circuit board; and

FIG. 10 is a pictorial view of an exemplary electronic device with an exemplary semiconductor chip device exploded therefrom.

### DESCRIPTION OF SPECIFIC EMBODIMENTS

Various lids useful to cover and convey heat from semiconductor chips mounted on circuit boards are disclosed. One arrangement includes a top hat design that has a top plate and two spaced-apart support legs that collectively define a recess to accommodate a board-mounted semiconductor chip. The recess include first and second openings to enable air flow around the semiconductor chip. At least one of the openings extends from the first support leg to the second support leg. Additional details will now be described.

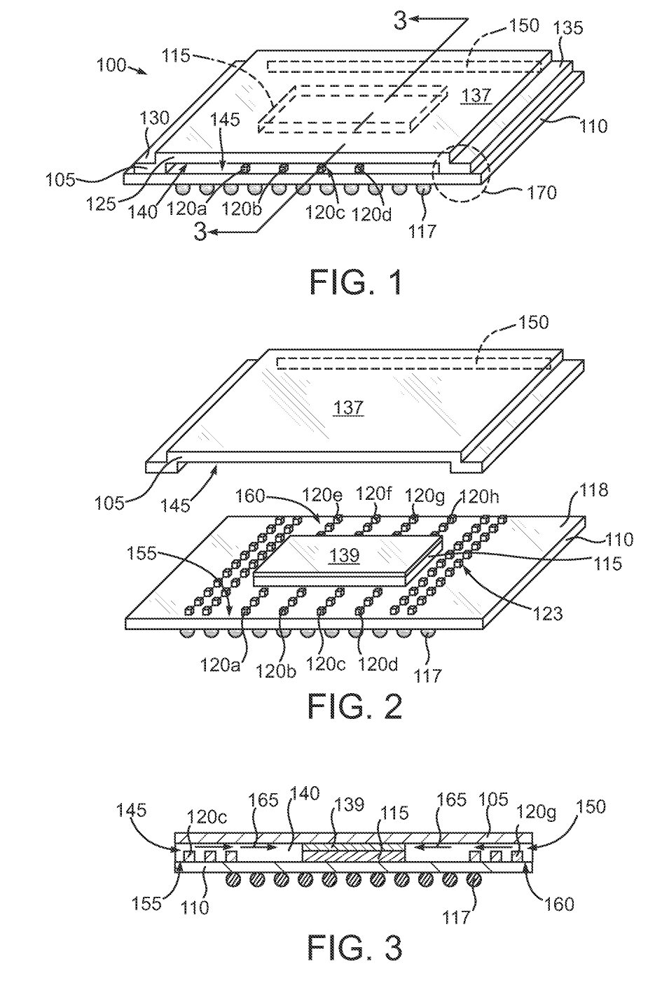

In the drawings described below, reference numerals are generally repeated where identical elements appear in more than one figure. Attention is turned to FIG. 1, which is a pictorial view and to FIG. 2, which is a partially exploded pictorial view of an exemplary embodiment of a semiconductor chip device 100 that may include a lid or heat spreader 105 mounted on a circuit board 110. A semiconductor chip 115 (shown in dashed) is mounted on the circuit board 110 underneath the lid 105. To interface the circuit board 110 and the semiconductor chip 115 with another circuit board or electronic device (not shown) the circuit board 110 may be provided with an interconnect systems that in this illustrative embodiment may be a ball grid array 117. Optionally, pin grid arrays, land grid arrays or types of interconnection schemes may be used. The circuit board 110 may be populated with surface components.

The semiconductor chip device 100 and any disclosed alternatives thereto may utilize many different configurations of the circuit board 110 and the semiconductor chip 115. For example, the circuit board 110 may be a package substrate, a circuit card, a system board or other type of circuit board. Monolithic or laminated structures, such as buildup may be used. If a buildup design is used, the circuit board 110 may consist of a central core upon which one or more build-up layers are formed and below which an additional one or more build-up layers are formed. The core itself may consist of a stack of one or more layers. The number of layers in the circuit board 110 can vary from four to sixteen or more, although less than four may be used. So-called “coreless” designs may be used as well. The layers of the circuit board 110 consist of an insulating material, such as various well-known epoxies or other resins, interspersed with metal interconnects. A multi-layer configuration other than buildup could be used. Optionally, the carrier substrate circuit board 110 may be composed of well-known ceramics or other materials suitable for package substrates or other printed circuit boards.

The top side 118 of the circuit board 110 may be populated with multiple components. Eight of these surface components are labeled 120a, 120b, 120c, 120d, 120e, 120f, 120g and 120h, and the remainder are collectively labeled 123. The components 120a, 120b, 120c, 120d, 120e, 120f, 120g, 120h and 123 may be passive devices such as capacitors, inductors or resistors or active devices such as integrated circuits.

Similarly, the semiconductor chip 115 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 115 may be constructed of bulk semiconductor, such as silicon or germanium, or semiconductor on insulator materials, such as silicon-on-insulators materials. The semiconductor chip 115 may be flip-chip mounted to the circuit board 110 and electrically connected thereto by solder joints, conductive pillars or other structures (not shown). Optionally, wire bonding may be used.

The lid 105 may be fabricated in a variety of configurations. In this illustrative embodiment, the lid 105 may be a top hat style configuration that includes a top plate 125 and two downwardly projecting support legs 130 and 135. The top plate 125 may include an upper flat surface 137 that is designed to be placed in thermal contact with a heat sink of one sort or another (not shown). The support legs 130 and 135 may be configured as flanges as shown or have other shapes as desired. Together, the top plate 125 and the support legs 130 and 135 define a recess 140. A thermal interface material 139 may be positioned between the semiconductor chip 115 and the lid 105. The thermal interface material 139 may be a thermal grease, a thermal paste, a solder or other. Indium and alloys thereof are examples of suitable solders. Unlike many conventional lids, the recess 140 has opposing side openings 145 and 150 where one or both extend from the support leg 130 to the other support leg 135. Some useful benefits flow from this configuration. First, the large side openings 145 and 150 permit the components 120a, 120b, 120c, 120d, 120e, 120f, 120g and 120h to be positioned very near the edges 155 and 160 of the circuit board 110. The edges 155 and 160 would be unavailable for component placement in conventional designs. Second, and as better seen in FIG. 3, which is a sectional view of FIG. 1 taken at section 3-3, a gas 165, such as air, may readily flow in and out of the side openings and through the recess 140 to provide better thermal management. As used herein the term “gas” includes a gas or gaseous mixture.

The lid 105 may be composed of well-known plastics, ceramics or metallic materials as desired. Some exemplary materials include nickel plated copper, anodized aluminum, aluminum-silicon-carbide, aluminum nitride, boron nitride or the like. A variety of fabrication techniques may be used, such as molding, casting, forging, machining, plating or combinations of these. In an exemplary embodiment, the lid 105 may consist of a copper core surrounded by a nickel jacket.

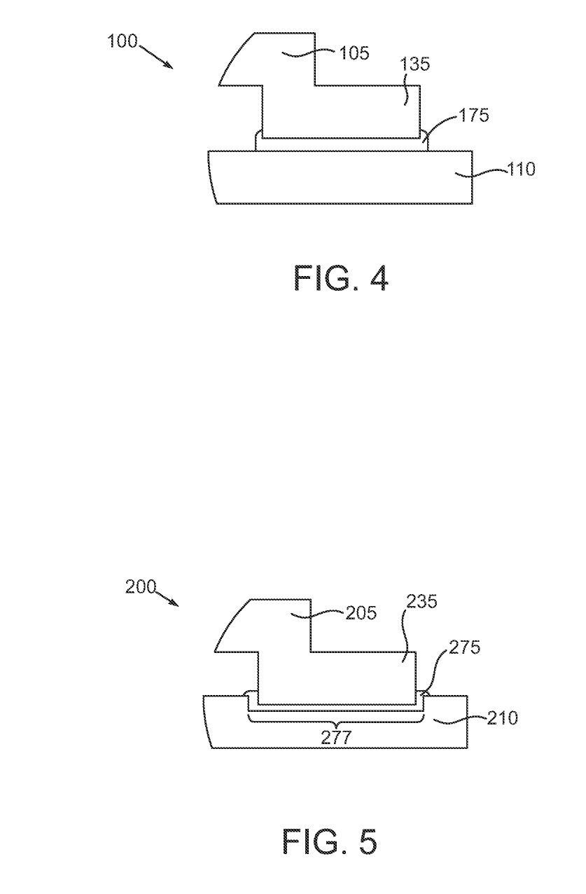

The portion of FIG. 1 circumscribed by the dashed oval 170 will be shown at greater magnification in FIG. 4 and used to illustrate additional features of the lid 105 and the circuit board 110. Attention is now turned to FIG. 4. Note that because FIG. 4 is a front view, no cross-hatching will appear. In this illustrative embodiment, the lid 105 may be secured to the circuit board 110 by an adhesive 175, which forms a bond between the support leg 135 and the circuit board 110. A similar adhesive portion would bond the support leg 130 to the circuit board 110 as well although that is not visible in FIG. 4. The adhesive 175 may be composed of a variety of different types of bonding materials, such as for example well-known epoxy adhesives or even various types of solders.

An alternate exemplary embodiment of a semiconductor chip device 200 that incorporates an alternative circuit board 210 may be understood by referring now to FIG. 5, which is a front view like FIG. 4. In other respects, the semiconductor chip device 200 may be similar to the semiconductor chip device 100 shown in FIGS. 1-3. Here, however, the circuit board 210 may be provided with a trench 277 that has the same general, albeit somewhat larger, footprint than the footprint of the support leg 235 of the lid 205. An adhesive 275, of the type described elsewhere herein, may be dispensed into the trench 277 and the support leg 235 depressed slightly into the adhesive 275 and the trench 277. This arrangement provides additional interfacial area between the support leg 235 and the adhesive 275. Such additional bonding interface area may be desirable if it is anticipated that the lack of support legs at all four sides of the lid 205 may not provide the requisite bonding strength to hold the lid 205 in place.

The trench 277 may be formed in a variety of ways. For example, if the circuit board is top coated with solder resist, then a partial depth lithographic process (mask, exposure and develop) could be used. Optionally, a chemical or laser etch or other process could be used.

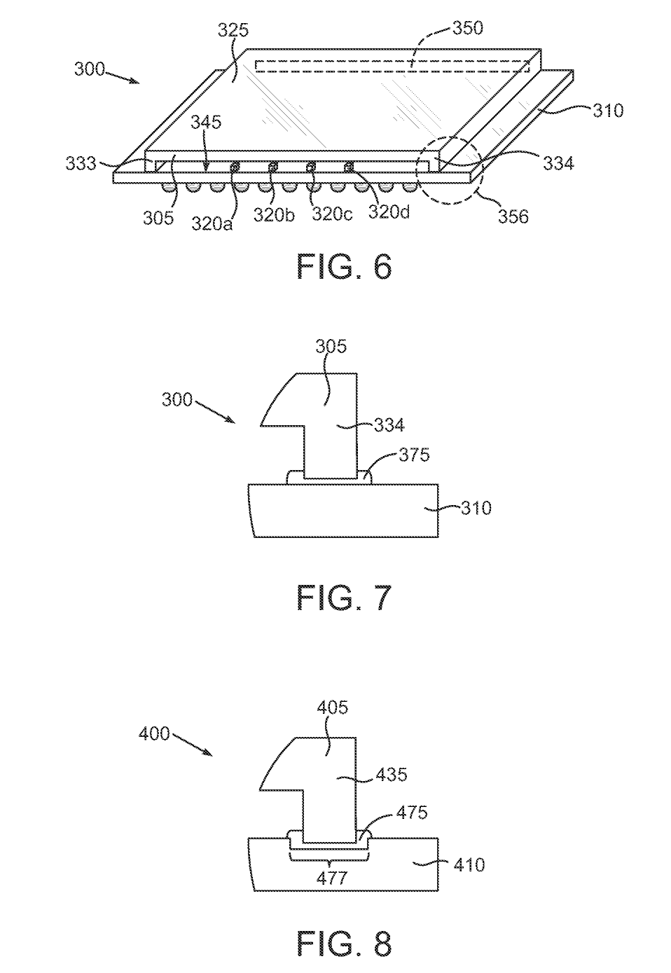

Another alternate exemplary embodiment of a semiconductor chip device 300 that incorporates a different lid configuration may be understood by referring now to FIG. 6, which is a pictorial view. The alternative lid 305 is mounted to a circuit board 310. The circuit board 310 may be configured like the circuit board 110 in FIGS. 1-3 and thus include components 320a, 320b, 320c and 320d (like the components 120a, 120b . . . etc.) and others that are not visible. Here, however, the lid 305 may be a bathtub design that includes a top plate 325 portion and downwardly projecting support legs 333 and 334 that are bonded to the circuit board 310 but do not use flanges. Like the other disclosed embodiments, the lid 305 has a recess 340 that is fully open at the one or both of the sides 345 and 350 of the circuit board 310. This provides the aforementioned thermal management benefits as well as enabling the placement of the components 320a, 320b, 320c and 320d and the corresponding components (not shown) at the side 350 as well. The lid 305 may be composed of the same types of materials and manufactured using the same techniques as described elsewhere herein.

The portion of FIG. 6 circumscribed by the dashed oval 356 will be shown in greater magnification in FIG. 7 and used to describe additional features of the lid 305 and the circuit board 310. Attention is now turned to FIG. 7. The lid 305 of the semiconductor chip device 300 may be secured to the circuit board 310 by an adhesive 375 that bonds the support leg 334 and the circuit board 310. A similar adhesive portion would bond the support leg 333 (see FIG. 6) to the circuit board 310 as well although that is not visible in FIG. 7. The adhesive 375 may be composed of a variety of different types of bonding materials, such as, for example well-known epoxy adhesives or even various types of solders.

Another alternate exemplary embodiment of a semiconductor chip device 400 that incorporates an alternative circuit board 410 may be understood by referring now to FIG. 8, which is a front view like FIG. 7. In other respects, the semiconductor chip device 400 may be similar to the semiconductor chip device 300 shown in FIGS. 6-7. Here, however, the circuit board 410 may be provided with a trench 477 that has the same general, albeit somewhat larger, footprint than the footprint of the support leg 435 of the lid 405. An adhesive 475, of the type described elsewhere herein, may be dispensed into the trench 477 and the support leg 435 depressed slightly into the adhesive 475 and the trench 477. This arrangement provides additional interfacial area between the support leg 435 and the adhesive 475. Such additional bonding interface area may be desirable if it is anticipated that the lack of support legs at all four sides of the lid 405 may not provide the requisite bonding strength to hold the lid 405 in place. As with the other disclosed embodiments, the opposite support leg may be positioned in a corresponding trench (not shown) in the circuit board 410. The trench 477 may formed using the same techniques disclosed elsewhere herein.

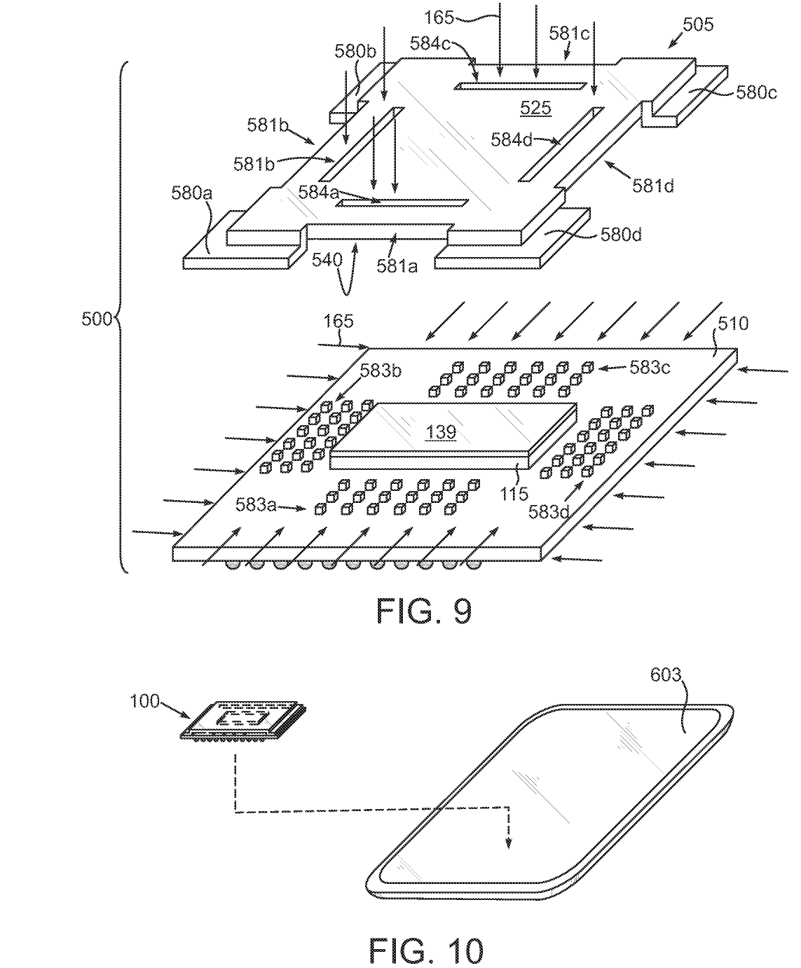

In the foregoing illustrative embodiments, side openings of the lids (e.g., 105 in FIGS. 1-3) are approximately co-extensive with the width of the lids' recesses, and the top plates of the lids are continuous. However, edge and other types of placements of circuit board components may be possible with another exemplary lid configuration. In this regard, attention is now turned to FIG. 9, which is a partially exploded pictorial view of an alternate exemplary embodiment of a semiconductor chip device 500. The semiconductor chip device 500 includes a lid 505 that may be mounted to a circuit board 510 to cover the semiconductor chip 115 and establish a thermal pathway via the thermal interface material 139. The circuit board 510 may be substantially identical to the other circuit boards 110, 210, 310 and 410 disclosed herein, albeit with a somewhat different arrangement for components. Here, however, the lid 505 may include a top plate 525 and corner support legs 580a, 580b, 580c and 580d. Cut outs 581a, 581b, 581c and 581d are provided between the corners support legs 580a, 580b, 580c and 580d to open to the recess 540 of the lid 505 at those locations. These cutouts 581a, 581b, 581c and 581d enable air to flow through the recess 540 to provide cooling, and permit edge location of groups 583a, 583b, 583c and 583d of components on the circuit board 510. In addition, the top plate 525 may be provided with slots 584a, 584b, 584c and 584d that lead to the recess 540 and provide additional pathways in and out flow of air 165 for enhanced cooling. Note that the lid 505 may be composed of the same types of materials, made using the same techniques, and used in the same techniques as generally disclosed above for the other embodiments. Note also that while the lid 505 is generally a top hat design, the same types of features may be incorporated into a bathtub design if desired.

Any of the disclosed embodiments of the semiconductor chip devices 100, 200, 300, 400 and 500 may be mounted on another electronic device. In this regard, attention is now turned to FIG. 10, which depicts the semiconductor chip device 100 exploded from an electronic device 603. The electronic device 603 may be a computer, a server, a hand held device, or virtually any other electronic component.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the structures disclosed herein. In an exemplary embodiment, an electronic design automation program, such as AutoCad, Solid Works or the like, may be used to synthesize the disclosed structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
fabricating a lid adapted to cover a semiconductor chip mounted on a circuit board, the lid having a top plate, a first support leg and a second support leg opposite the first support leg adapted to support the lid on the circuit board, the first and second support legs and the top plate defining a recess to accommodate the semiconductor chip, the recess having a first opening and a second opening; and
wherein at least one of the first and second openings extends from the first support leg to the second support leg.

2. The method of claim 1, comprising forming the first and second openings to extend from the first support leg to the second support leg.

3. The method of claim 1, comprising forming the first and second support legs as flanges.

4. The method of claim 1, comprising coupling a circuit board to the lid.

5. The method of claim 4, comprising mounting the circuit board in an electronic device.

6. A method of conveying heat from a semiconductor chip mounted on a circuit board, comprising:
coupling a lid to the circuit board in thermal contact with the semiconductor chip, the lid having a top plate, a first support leg and a second support leg opposite the first support leg adapted to support the lid on the circuit board, the first and second support legs and the top plate defining a recess to accommodate the semiconductor chip, the recess having a first opening and a second opening; and
wherein at least one of the first and second openings extends from the first support leg to the second support leg to enable a gas to flow between the first and second openings to cool the semiconductor chip.

7. The method of claim 6, wherein the coupling the lid comprises positioning the first and second support legs in first and second trenches in the circuit board, the first and second trenches containing an adhesive.

8. The method of claim 6, comprising mounting the circuit board in an electronic device.

9. An apparatus, comprising:
a lid adapted to cover a semiconductor chip mounted on a circuit board, the lid having a top plate, a first support leg and a second support leg opposite the first support leg adapted to support the lid on the circuit board, the first and second support legs and the top plate defining a recess to accommodate the semiconductor chip, the recess having a first opening and a second opening; and
wherein at least one of the first and second openings extends from the first support leg to the second support leg.

10. The apparatus of claim 9, wherein each of the first and second openings extends from the first support leg to the second support leg.

11. The apparatus of claim 9, wherein the first and second support legs comprise flanges.

12. The apparatus of claim 9, comprising a circuit board coupled to the lid.

13. The apparatus of claim 12, comprising an electronic device, the circuit board being mounted in the electronic device.

14. The apparatus of claim 12, wherein the circuit board comprises first and second trenches containing an adhesive, the first support leg being positioned in the first trench and the second leg support being positioned in the second trench.

15. An apparatus, comprising:
a circuit board;
a semiconductor chip mounted on the circuit board; and
lid mounted on the circuit board, the lid having a top plate, a first support leg and a second support leg opposite the first support leg to support the lid on the circuit board, the first and second support legs and the top plate defining a recess to accommodate the semiconductor chip, the recess having a first opening and a second opening; and
wherein at least one of the first and second openings extends from the first support leg to the second support leg.

16. The apparatus of claim 15, wherein each of the first and second openings extends from the first support leg to the second support leg.

17. The apparatus of claim 15, wherein the first and second support legs comprise flanges.

18. The apparatus of claim 15, comprising a circuit board coupled to the lid.

19. The apparatus of claim 18, comprising an electronic device, the circuit board being mounted in the electronic device.

20. The apparatus of claim 18, wherein the circuit board comprises first and second trenches containing an adhesive, the first support leg being positioned in the first trench and the second support leg being positioned in the second trench.

21. A method of manufacturing, comprising:
fabricating a lid adapted to cover a semiconductor chip mounted on a circuit board, the lid having a top plate, a first support leg and a second support leg opposite the first support leg adapted to support the lid on the circuit board, the first and second support legs and the top plate defining a recess to accommodate the semiconductor chip, the recess having a first opening and a second opening; and
wherein at least one of the first and second openings extends between first support leg and the second support leg, at least one of the first and second openings being substantially at least as large as the recess.
